(19) United States
(12) Patent Application Publication
(10) Pub. No.: US 2023/0301209 A1
(43) Pub. Date: Sep. 21, 2023

(54) SEMICONDUCTOR STORAGE DEVICE

(71) Applicant: KIOXIA CORPORATION, Tokyo (JP)

(72) Inventors: Hiroyuki ODE, Yokkaichi Mie (JP); Yuki OHNISHI, Yokkaichi Mie (JP); Ibuki WATANABE, Mie Mie (JP)

(21) Appl. No.: 17/901,690

(22) Filed: Sep. 1, 2022

(30) Foreign Application Priority Data
Mar. 1, 2022 (JP) 2022-030690

(51) Int. Cl. H01L 45/00; H01L 27/24

(52) U.S. Cl. CPC H01L 45/06; H01L 27/2409; H01L 27/2463; H01L 45/144

(57) ABSTRACT

According to one embodiment, a semiconductor storage device includes a first electrode and a second electrode spaced in a first direction and a phase change layer provided between the first electrode and the second electrode. The phase change layer comprises at least one of germanium (Ge), antimony (Sb), and tellurium (Te). The phase change layer is configured to be able to transition to a first state in which a volume ratio of an amorphous phase to a crystalline phase is a first ratio, a second state in which the volume ratio is a second ratio larger than the first ratio, and a third state in which the volume ratio is a third ratio larger than the second ratio.

### CROSS-REFERENCE TO RELATED APPLICATION(S)

This application is based upon and claims the benefit of priority from Japanese Patent Application No. 2022-030690, filed Mar. 1, 2022, the entire contents of which are incorporated herein by reference.

### FIELD

Embodiments described herein relate generally to a semiconductor storage device.

### BACKGROUND

A semiconductor storage device including a first electrode, a second electrode, and a phase change layer provided between the first electrode and the second electrode is known. The phase change layer contains, for example, germanium (Ge), antimony (Sb), tellurium (Te), or the like.

### BRIEF DESCRIPTION OF THE DRAWINGS

FIG. 1 is a schematic circuit diagram of a semiconductor storage device according to a first embodiment.

FIG. 2 is a schematic perspective view of a semiconductor storage device.

FIGS. 3A and 3B are schematic cross-sectional views of a semiconductor storage device.

FIG. 4 depicts aspects related to a set operation of a semiconductor storage device.

FIG. 5 provides schematic cross-sectional views illustrating a resistance changing element of a semiconductor storage device.

FIG. 6 provides schematic waveforms related to a set operation of a semiconductor storage device.

FIG. 7 provides schematic waveforms related to a set operation of a semiconductor storage device.

FIG. 8 provides schematic waveforms related to a set operation of a semiconductor storage device.

FIG. 9 is a schematic graph illustrating aspects related to a set operation of a semiconductor storage device.

FIG. 10 is a schematic graph depicting current-voltage characteristics of a semiconductor storage device.

FIG. 11 is a schematic graph illustrating aspects related to a set operation of a semiconductor storage device according to a comparative example.

FIG. 12 is a schematic cross-sectional view of a semiconductor storage device according to a first embodiment.

FIG. 13 is a schematic cross-sectional view of a semiconductor storage device.

FIG. 14 provides schematic waveforms related to a set operation of a semiconductor storage device according to a second embodiment.

FIG. 15 provides schematic waveforms related to a set operation of a semiconductor storage device according to a second embodiment.

FIG. 16 provides schematic waveforms related to a set operation of a semiconductor storage device according to a second embodiment.

### DETAILED DESCRIPTION

Embodiments provide a semiconductor storage device with a large capacity.

In general, according to one embodiment, a semiconductor storage device includes a first electrode and a second electrode spaced from one another in a first direction and a phase change layer provided between the first electrode and the second electrode. The phase change layer comprises at least one of germanium (Ge), antimony (Sb), and tellurium (Te). The phase change layer is configured to be able to transition to a first state in which a volume ratio of an amorphous phase to a crystalline phase is a first ratio, a second state in which the volume ratio is a second ratio larger than the first ratio, and a third state in which the volume ratio is a third ratio larger than the second ratio.

Next, the semiconductor storage device according to certain example embodiments will be described with reference to the drawings. The following embodiments are merely examples and are not intended to limit the present disclosure. Further, the drawings are schematic and some configurations and the like may be omitted for convenience of explanation. In addition, the same reference numerals are given to the portions common to the plurality of embodiments and the description thereof may be omitted.

The term “semiconductor storage device” in the present disclosure may mean a memory die or may mean a memory system including a controller die, a memory chip, a memory card, or an SSD (Solid State Drive). Further, the term “semiconductor storage device” may mean a configuration including or integrating a host computer such as a smartphone, a tablet terminal, and a personal computer.

Further, when a first component is said to be “connected between” a second and a third component, the first component, the second component, and the third component may be connected in series and the second component may be connected to the third component via the first component.

In the description, one direction parallel to an upper surface of a substrate is called an X direction, a direction parallel to the upper surface of the substrate but perpendicular to the X direction is called a Y direction, and a direction orthogonal to the upper surface of the substrate is called a Z direction.

In the present disclosure, a direction along a predetermined surface is a first direction, a direction intersecting the first direction along the predetermined surface is a second direction, and a direction intersecting the predetermined surface is a third direction. The first direction, the second direction, and the third direction may or may not correspond to any of the X direction, the Y direction, and the Z direction.

Expressions used in the description such as “upper” and “lower” reference the positional relationship of substrate. For example, a direction going away from the substrate along the Z direction is called an upper or upward direction and a direction going toward the substrate along the Z direction is called a lower or downward direction. A lower surface or a lower end refers to a surface or an end portion on a substrate side of a configuration, and an upper surface or an upper end means a surface or an end portion on an opposite side from the substrate. Further, a surface that intersects an XY plane can be referred to as a side surface or the like.

Further, in the present specification, in the description of a configuration, a member, and the like, “width”, “length”, “thickness”, and the like in a predetermined direction may mean a width, a length, a thickness, and the like in a cross section observed by SEM (Scanning electron microscopy), TEM (Transmission electron microscopy), or the like.

### First Embodiment

### Semiconductor Storage Device Configuration

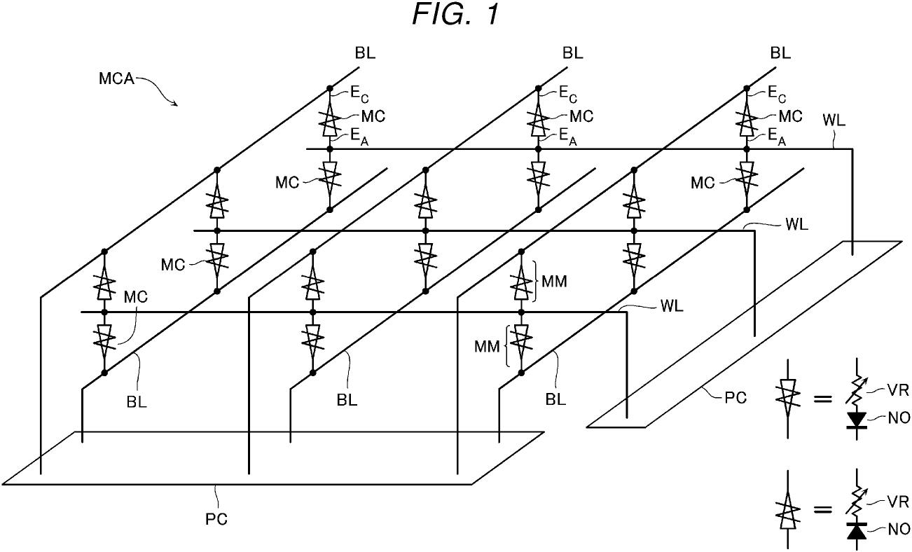

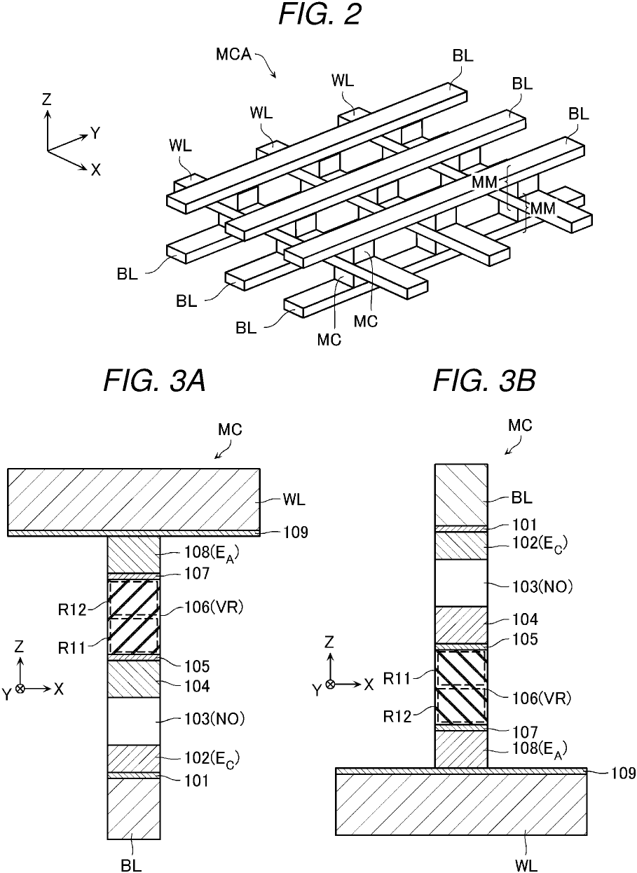

FIG. 1 is a schematic circuit diagram showing a partial configuration of a semiconductor storage device according to a first embodiment. FIG. 2 is a schematic perspective view showing a partial structural configuration of the semiconductor storage device.

The semiconductor storage device according to the first embodiment includes a memory cell array MCA and a peripheral circuit PC that controls the memory cell array MCA.

For example, as shown in FIG. 2, the memory cell array MCA includes a plurality of memory mats MM spaced in the Z direction. The memory mat MM includes a bit line BL, a word line WL, and a memory cell MC. A plurality of bit lines BL are spaced the X direction and extend in the Y direction. A plurality of word lines WL are spaced in the Y direction and extend in the X direction. A plurality of memory cells MC are arranged in the X direction and the Y direction at positions corresponding to the intersections/crossings of bit lines BL and the word lines WL. As shown in the drawing, a bit line BL or a word line WL may be shared by two memory mats MM adjacent in the Z direction. In an example of FIG. 1, a cathode E_{C} of the memory cell MC is connected to the bit line BL. Further, an anode E_{A} of the memory cell MC is connected to the word line WL. A positive voltage is supplied to an anode E_{A} side in the memory cell MC with a cathode E_{C} side as a reference. The memory cell MC includes a resistance changing element VR and a nonlinear element NO.

The peripheral circuit PC is connected to the bit line BL and the word line WL. The peripheral circuit PC includes, for example, a step-down circuit, a selection circuit, a sense amplifier circuit, a sequencer for controlling these circuits, and the like. The step-down circuit steps down a power supply voltage and outputs the voltage to a voltage supply line. The selection circuit conducts the bit line BL and the word line WL corresponding to a selected address with the corresponding voltage supply line. The sense amplifier circuit outputs data according to a voltage or a current of the bit line BL. Configuration of Memory Cell MC

FIGS. 3A and 3B are schematic cross-sectional views of the memory cell MC according to the first embodiment. In FIG. 3A, a bit line BL is provided below, and a word line WL is provided above. In FIG. 3B, a word line WL is provided below, and a bit line BL is provided above.

The memory cell MC shown in FIG. 3A includes a conductive layer 102, a selector layer 103, a conductive layer 104, a barrier conductive layer 105, a phase change layer 106, a barrier conductive layer 107, and a conductive layer 108, which are sequentially stacked on a barrier conductive layer 101 on an upper surface of the bit line BL. The conductive layer 108 is provided with a barrier conductive layer 109 on a lower surface of the word line WL.

The barrier conductive layer 101 functions as a part of the bit line BL. The barrier conductive layer 101 may be, for example, tungsten nitride (WN), titanium nitride (TiN), or the like, or may be another conductive layer such as tungsten carbonitride (WCN) or tungsten carbide nitride silicide (WCNSi).

The conductive layer 102 is connected to a bit line BL provided directly under the memory cell MC and functions as the cathode E_{C} of the memory cell MC. The conductive layer 102 may be, for example, carbon (C), carbon nitride (CN), or the like, or may be tungsten (W), tungsten nitride (WN), titanium (Ti), titanium nitride (TiN), vanadium (V), vanadium nitride (VN), zirconium (Zr), zirconium nitride (ZrN), hafnium (Hf), hafnium nitride (HfN), yttrium (Y), yttrium nitride (YN), scandium (Sc), scandium nitride (ScN), tantalum (Ta), tantalum nitride (TaN), molybdenum (Mo), rhenium (Re), niobium (Nb), aluminum (Al), and the like. Further, the conductive layer 102 may be, for example, polycrystalline silicon or the like in which N-type impurities such as phosphorus (P) are injected, or may be another conductive layer such as tungsten carbide (WC), tungsten carbonitride (WCN) or tungsten carbide nitride silicide (WCNSi).

The selector layer 103 functions as the nonlinear element NO and may be, for example, a switch element between two terminals. When a voltage applied between the two terminals is a threshold voltage V_{TH_SEL} or less, the switch element is in a high resistance state (e.g., an electrically non-conductive state). When the voltage applied between the two terminals is equal to or higher than the threshold voltage V_{TH_SEL}, the switch element changes to a low resistance state (e.g., an electrically conductive state). The switch element may have this function regardless of polarity of the voltage.

The conductive layer 104 functions as an electrode for connecting the nonlinear element NO and the resistance changing element VR. The conductive layer 104 may contain, for example, the same material as the conductive layer 102.

The barrier conductive layer 105 may be, for example, the same material as the barrier conductive layer 101.

The phase change layer 106 functions as a resistance changing element VR. The resistance changing element VR can be reversibly changed into three different resistance states including, for example, the low resistance state, the high resistance state, and a medium resistance state in which a resistance value is between the low resistance state and the high resistance state. Details of the phase change layer 106 will be described later.

The barrier conductive layer 107 may be, for example, the same material as the barrier conductive layer 101.

The conductive layer 108 is connected to a word line WL provided directly above the memory cell MC and functions as the anode E_{A} of the memory cell MC. The conductive layer 108 may be, for example, the same material as the conductive layer 102.

The barrier conductive layer 109 functions as a part of the word line WL. The barrier conductive layer 109 may be, for example, the same material as the barrier conductive layer 101.

The memory cell MC shown in FIG. 3B is similar to the memory cell MC shown in FIG. 3A. However, in the memory cell MC shown in FIG. 3B, the bit line BL is located above and the word line WL is located below, and a stacked structure from the barrier conductive layer 101 to the conductive layer 108 is provided in a reverse stacking order along the Z direction as the memory cell MC shown in FIG. 3A.

### Resistance Changing Element VR

### Phase Change Layer 106

The phase change layer 106 that functions as the resistance changing element VR is composed of, for example, a material capable of changing a volume content ratio of the crystalline phase and the amorphous phase. The volume content ratio between the crystalline phase and the amorphous phase can be changed, for example, by heating and heat dissipation of the phase change layer 106. For this heating and heat dissipation, for example, Joule heat accompanying an applied current is used.

The phase change layer 106 undergoes crystallization by a heating for a certain period of time at a temperature lower than a melting temperature but higher than a crystallization temperature. The crystalline phase is a low resistance state. The phase change layer 106 becomes the amorphous phase (high resistance state) by heating to the melting temperature or higher followed by a rapid cooling to solidify the previously molten (melted) material without providing the time required for crystallizing after the melting. The phase change layer 106 can have in an intermediate state (medium resistance state) including both an amorphous phase and a crystalline phase. Such an intermediate state can be provided by generating, for example, a temperature gradient and/or a composition gradient in the phase change layer 106. In the intermediate state, for example, as shown in FIGS. 3A and 3B, a region R11 on the cathode E_{C} side contains a large amount of amorphous phase material, and a region R12 closer to the anode E_{A} than is the region R11 contains a large amount of crystalline phase material.

To permit a temperature gradient to be created in the phase change layer 106, the memory cell MC can have a structure in which heat more easily escapes to the anode E_{A} side of the phase change layer 106 as compared to cathode E_{C} side. In such a case, a temperature gradient is generated such that a temperature on the anode E_{A} side of the phase change layer 106 is lower and a temperature on the cathode E_{C} side is higher, and a temperature in the region R11 thus tends to be higher than a temperature in the region R12. Therefore, it is possible to heat the region R12 to a temperature lower than the melting temperature but higher than the crystallization temperature while heating the region R11 to the melting temperature or higher. A structural example of the memory cell MC suitable for forming a temperature gradient will be described below.

To create a composition gradient in the phase change layer 106, an element of the material forming the phase change layer 106 that might move (migrate) to the anode E_{A} or cathode E_{C} side depending on an ionic valence thereof when voltage is supplied can be utilized. In the following description, an example will be described in which a main component of the phase change layer 106 is a Ge—Sb—Te based chalcogenide compound (GST).

Among the elements that make up GST, tellurium (Te), which has a negative valence, is particularly easy to cause to move by application of voltage. Therefore, when a voltage is supplied to the phase change layer 106, a portion of the tellurium (Te) moves to the anode E_{A} side, and thus, the region R12 on the anode E_{A} side has a composition rich with tellurium (Te), and the region R11 on the cathode E_{C} side has a composition depleted of tellurium (Te).

It is known that a melting point of GST increases with increases in the amount of tellurium (Te) in the material. For example, when a ratio of tellurium (Te) to antimony (Sb) is 60:40, the melting point is about 800 K, but when the ratio of Te to Sb is 75:25, the melting point is about 870 K.

Therefore, a melting point of the region R12 on the anode E_{A} side having a composition with a larger amount of tellurium (Te) can be increased, and a melting point of the region R11 on the cathode E_{C} side having a composition with a smaller amount of tellurium (Te) can be decreased.

By utilizing such a temperature gradient and/or composition gradient, it is possible to form an intermediate state in which an amorphous phase (high resistance state) on the cathode E_{C} side and a crystalline phase (low resistance state) on the anode E_{A} side coexist. The phase change layer 106 as a whole shows a resistance value between resistance values of the full amorphous phase and the full crystalline phase due to the coexistence of the amorphous crystalline phases in the intermediate state.

Although the Ge—Sb—Te chalcogenide compound (GST) is described above, the phase change layer 106 in other examples may comprise at a chalcogen. The phase change layer 106 may be, for example, chalcogenide, which is a compound containing a chalcogen. The phase change layer 106 may be, for example, GeCuTe, GeTe, SbTe, SiTe, or the like. Further, the phase change layer 106 may contain at least one element selected from germanium (Ge), antimony (Sb), and tellurium (Te). Further, the phase change layer 106 may contain nitrogen (N), carbon (C), boron (B), and the like.

The composition of each region of the phase change layer 106 can be observed by, for example, a method such as EDS (Energy Dispersive X-ray Spectrometry).

The melting point in each region of the phase change layer 106 can be analyzed by, for example, observing a cross section TEM (Transmission Electron Microscope) while the temperature of the memory cell MC is ramped to measure a temperature at which the crystal structure is not maintained. In addition, a melting point of each material can be estimated from literature values referred to from the composition and the like.

### Three Resistance States of Resistance Changing Element VR

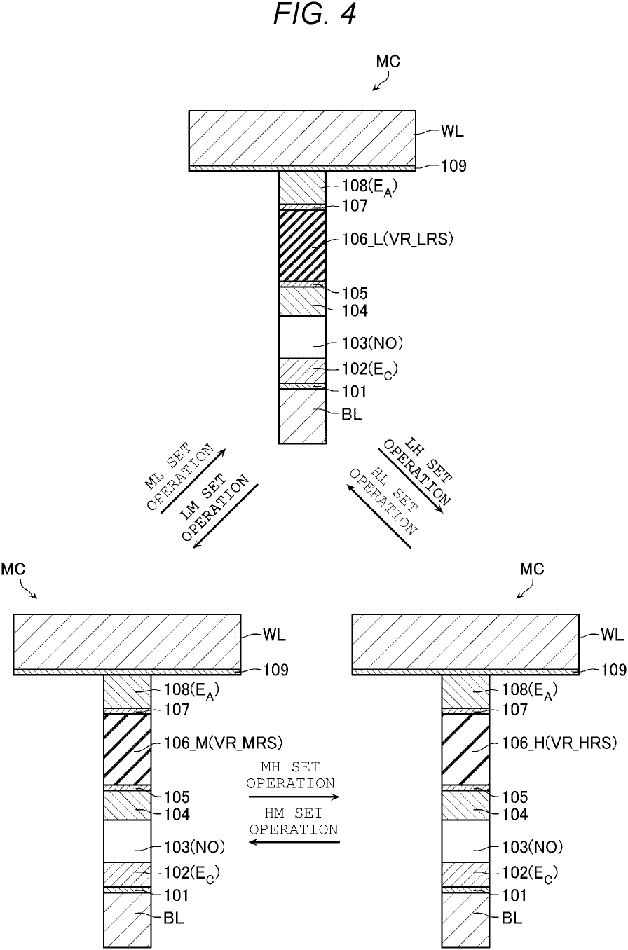

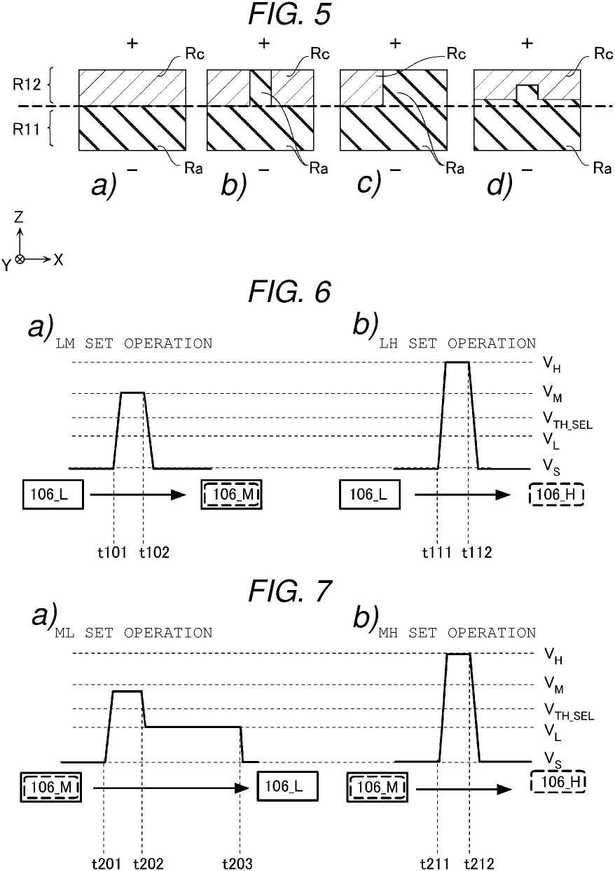

Next, the three resistance states of the resistance changing element VR will be described with reference to FIG. 4 and FIG. 5. FIG. 4 is a schematic relationship diagram illustrating three resistance states and aspects of a set operation of a resistance changing element VR according to the present embodiment. FIG. 4 shows, as resistance states of the resistance changing element VR, a resistance changing element VR_LRS (low resistance state_, a resistance changing element VR_MRS (medium resistance state), and a resistance changing element VR_HRS (high resistance state). FIG. 5 depicts schematic cross-sectional views illustrating the resistance changing element VR_MRS in the medium resistance state.

### Resistance Changing Element VR_LRS in Low Resistance State

The resistance changing element VR_LRS is, for example, a state in which the phase change layer 106 is transitioning to a first phase 106_L, which is the low resistance state.

The first phase 106_L has a volume ratio of the crystalline phase to total volume (of the phase change layer 106) that is greater than 90%. Further, the first phase 106_L has a volume ratio of the amorphous phase to total volume (of the phase change layer 106) that is less than 10%. The first phase 106_L exhibits a relatively low resistance value since the crystalline phase having a low resistance value exists in a large amount.

### Resistance Changing Element VR_MRS in Medium Resistance State

The resistance changing element VR_MRS is, for example, a state in which the phase change layer 106 is transitioning to a second phase 106_M, which is the medium resistance state.

The second phase 106_M has a volume ratio of the crystalline phase to total volume (of the phase change layer 106) that is in a range from 10% to 90%. Further, the second phase 106_M has a volume ratio of the amorphous phase to total volume (of the phase change layer 106) that is in a range from 90% to 10%. The second phase 106_M shows a resistance value in accordance with the volume ratio of the amorphous phase and the crystalline phase.

For examples of a crystal state in the second phase 106_M are shown in FIG. 5. In FIG. 5, a region containing the amorphous phase is shown as an amorphous region Ra, and a region containing the crystalline phase is shown as a crystal region Rc. Further, an upper part of the drawing sheet is labeled “+” as the anode E_{A} side, and a lower part of the drawing sheet is labeled “-” as the cathode E_{C} side.

FIG. 5, part a, shows, as an example of the second phase 106_M, a case where almost 100% of the region R11 on the cathode E_{C} side is the amorphous region Ra and almost 100% of the region R12 on the anode E_{A} side is the crystal region Rc.

FIG. 5, part b, as another example of the second phase 106_M, almost 100% of the region R11 on the cathode E_{C} side is the amorphous region Ra, about 80% of the region R12 on the anode E_{A} side is the crystal region Rc, and about 20% of the region R12 is the amorphous region Ra. In the example shown in FIG. 5, part b, both the crystal region Rc and the amorphous region Ra in the region R12 are formed in contact with the anode

E_{A} side (for example, in contact with the barrier conductive layer 107 in FIG. 3A). Further, the crystal region Rc is formed within a predetermined distance range from both side surfaces of the region R12 in the X direction and the Y direction, and the amorphous region Ra is formed outside the predetermined distance range. In the case of a structure or the like in which heat can be more easily dissipated in the X direction or the Y direction, the temperature at a position between the X direction or the Y direction tends to be relatively high, and the second phase 106_M as shown in FIG. 5, part b is formed.

In FIG. 5, part c, as another example of the second phase 106_M, almost 100% of the region R11 on the cathode E_{C} side is the amorphous region Ra, about 40% of the region R12 on the anode E_{A} side is the crystal region Rc, and about 60% of the region R12 is the amorphous region Ra. Both the crystal region Rc and the amorphous region Ra in the region R12 are formed in contact with the anode E_{A} side (for example, the barrier conductive layer 107 in FIG. 3A). Furthermore, the crystal region Rc is formed in a predetermined distance range from one side surface in the X direction or the Y direction of the region R12, and the amorphous region Ra is formed outside the predetermined distance range. When heat is more easily dissipated to one side in the X direction or the Y direction, the second phase 106_M as shown in FIG. 5, part c is formed.

In FIG. 5, part d, as another example of the second phase 106_M, almost 100% of the region R11 on the cathode E_{C} side is the amorphous region Ra, about 90% of the region R12 on the anode E_{A} side is the crystal region Rc, and about 10% is the amorphous region Ra. The crystal region Rc in the region R12 is formed in contact with the anode E_{A} side (for example, the barrier conductive layer 107 in FIG. 3A), while the amorphous region Ra in the region R12 is formed at a position in contact with the region R11 without contacting the anode E_{A} side (for example, the barrier conductive layer 107 in FIG. 3A). When the width in the X direction or the Y direction is relatively wide and the central portion in the X direction or the Y direction finds it difficult to dissipate heat, the second phase 106_M as shown in FIG. 5, part d is formed.

A distribution of the crystal region Rc and the amorphous region Ra in the second phase 106_M may be in a distribution other than those illustrated in FIG. 5. The distribution of the crystal region Rc and the amorphous region Ra of the second phase 106_M only needs to satisfy the condition that the volume ratio of the crystal region Rc to the total volume of the phase change layer 106 is between 10% to 90%.

### Resistance Changing Element VR_HRS in High Resistance State

The resistance changing element VR_HRS (FIG. 4) is, for example, a state in which the phase change layer 106 is transitioning to a third phase 106_H, which is the high resistance state.

The third phase 106_H has a volume ratio of the crystalline phase to total volume (of the phase change layer 106) is less than 10%, and the volume ratio of the amorphous phase to total volume (of the phase change layer 106) is greater than 90%. The third phase 106_H exhibits a relatively high resistance value since the amorphous phase having a high resistance value exists in a large amount.

### Set Operation of Resistance Changing Element VR

Next, a set operation for each of the resistance changing elements VR_LRS, VR_MRS, and VR_HRS will be described with reference to FIG. 4 and FIG. 6 to FIG. 8. FIG. 4 illustrates an LM set operation, an LH set operation, an ML set operation, an MH set operation, an HL set operation, and an HM set operation as six types of set operations. FIG. 6 to FIG. 8 are schematic waveform diagrams illustrating these different types of set operations. FIG. 6 to FIG. 8 show a voltage of the anode E_{A} (hereinafter referred to as “cell voltage Vcell”) supplied to the memory cell MC in each set operation when a voltage of the cathode E_{C} is used as a reference.

### LM Set Operation

As shown in FIG. 4, the LM set operation is an operation of changing the resistance changing element VR_LRS to the resistance changing element VR_MRS. By the LM set operation, the phase change layer 106 changes from the first phase 106_L to the second phase 106_M.

In the LM set operation, as shown in FIG. 6, part a, a voltage V_{M} begins to be supplied to the memory cell MC at a timing t101. The voltage V_{M} is larger than the threshold voltage V_{TH}__{SEL} of the selector layer 103. At the voltage V_{M}, the region R11 on the cathode E_{C} side is heated to the melting temperature or higher due to the temperature gradient and the composition gradient described above, but the region R12 on the anode E_{A} side is kept at a temperature below the melting temperature.

Next, at a timing t102, a voltage V_{S} is supplied to the memory cell MC. The voltage V_{S} is a voltage at which no current flows through the memory cell MC and the Joule heat supply is eliminated. The voltage V_{S} may be, for example, a ground voltage (0V). By supplying the voltage V_{S}, the amorphous region Ra is formed in the region R11 by rapid cooling, and the region R12 is still kept at a temperature below the melting temperature, and thus, the crystal region Rc is maintained. In this way, the phase change layer 106 changes to the second phase 106_M in the medium resistance state by the LM set operation.

### LH Set Operation

As shown in FIG. 4, the LH set operation is an operation of changing the resistance changing element VR_LRS to the resistance changing element VR_HRS. By the LH set operation, the phase change layer 106 changes from the first phase 106_L to the third phase 106_H.

In the LH set operation, as shown in FIG. 6, part b, a voltage V_{H} begins to be supplied to the memory cell MC at a timing t111. The voltage V_{H} is larger than the voltage V_{M}. The voltage V_{H} is a voltage at which both the region R11 and the region R12 are heated to the melting temperature or higher.

Next, at a timing t112, the voltage V_{S} is supplied to the memory cell MC. By supplying the voltage V_{S}, the amorphous region Ra is formed in the region R11 and the region R12 by rapid cooling. In this way, the phase change layer 106 changes to the third phase 106_H in the high resistance state by the LM set operation.

### ML Set Operation

As shown in FIG. 4, the ML set operation is an operation of changing the resistance changing element VR_MRS to the resistance changing element VR_LRS. By the ML set operation, the phase change layer 106 changes from the second phase 106_M to the first phase 106_L.

In the ML set operation, as shown in FIG. 7, part a, a voltage having a magnitude between the voltage V_{M} and the threshold voltage V_{TH_SEL} of the selector layer 103 begins to be supplied to the memory cell MC at a timing t201.

Next, at a timing t202, the voltage V_{L} begins to be supplied to the memory cell MC, a voltage V_{L} is supplied from the timing t202 to a timing t203, and then the voltage V_{S} is supplied at the timing t203. The voltage V_{L} is smaller than the threshold voltage V_{TH_SEL} of the selector layer 103. The voltage V_{L} is a voltage at which both the region R11 and the region R12 are heated to a temperature that is lower than the melting temperature but higher than the crystallization temperature to form the crystal region Rc in the region R11 and the region R12. In this way, the phase change layer 106 changes to the first phase 106_L in the low resistance state by the ML set operation.

### MH Set Operation

As shown in FIG. 4, the MH set operation is an operation of changing the resistance changing element VR_MRS to the resistance changing element VR_HRS. The phase change layer 106 changes from the second phase 106_M to the third phase 106_H by the MH set operation.

In the MH set operation, as shown in FIG. 7, part b, the voltage V_{H} begins to be supplied to the memory cell MC at a timing t211. The regions R11 and R12 are heated to the melting temperature or higher by the voltage V_{H}, similar to the LH set operation.

Next, at a timing t212, the voltage V_{S} is supplied to the memory cell MC. By supplying the voltage V_{S}, the amorphous region Ra is formed in the region R11 and the region R12 as in the LH set operation. Therefore, the phase change layer 106 changes to the third phase 106_H in the high resistance state by the MH set operation.

### HL Set Operation

As shown in FIG. 4, the HL set operation is an operation of changing the resistance changing element VR_HRS to the resistance changing element VR_LRS. By the HL set operation, the phase change layer 106 changes from the third phase 106_H to the first phase 106_L.

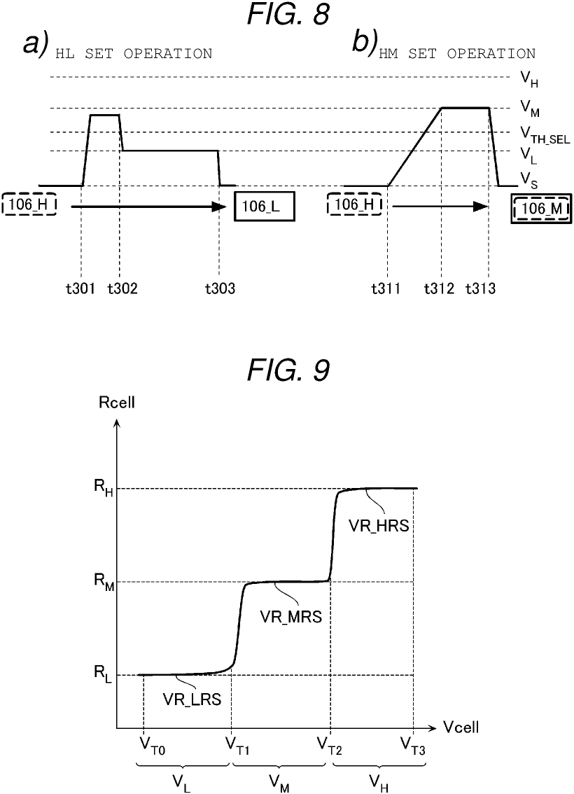

In the HL set operation, as shown in FIG. 8, part a, a voltage having a magnitude between the voltage V_{M} and the threshold voltage V_{TH_SEL} of the selector layer 103 begins to be supplied to the memory cell MC at a timing t301.

Next, at a timing t302, the voltage V_{L} begins to be supplied to the memory cell MC, the voltage V_{L} is supplied from the timing t302 to a timing t303, and then the voltage V_{S} is supplied at the timing t303.

As a result, the crystal region Rc is formed in both the region R11 and the region R12, as in the ML set operation. Therefore, the phase change layer 106 changes to the first phase 106_L in the low resistance state by the HL set operation.

### HM Set Operation

As shown in FIG. 4, the HM set operation is an operation of changing the resistance changing element VR_HRS to the resistance changing element VR_MRS. The phase change layer 106 changes from the third phase 106_H to the second phase 106_M by the HM set operation.

In the HM set operation, as shown in FIG. 8, part b, a voltage supplied to the memory cell MC increases (ramps) from a timing t311 to a timing t312 from the voltage V_{S} to the voltage V_{M}.

Next, after supplying the voltage V_{M} from the timing t312 to the timing t313, the voltage V_{S} is supplied at the timing t313.

By gradually heating from timing t311 to timing t312 for a relatively long time, the region R12 is heated at a temperature lower than the melting temperature but higher than the crystallization temperature for a certain period of time, and the crystal region Rc is formed. The region R11 reaches the melting temperature in the process by the continuous heating (ramping) but then is rapidly cooled by the supply of the voltage V_{S}, and the amorphous region Ra is formed again in region R11. Therefore, the phase change layer 106 changes to the second phase 106_M in the medium resistance state by the HM set operation.

The time required for raising and lowering the voltage in these six set operations (the LM set operation, the LH set operation, the ML set operation, the MH set operation, the HL set operation, and the HM set operation) may be, for example, less than 50 nsec (nanoseconds). However, in some examples, the time required for raising the voltage in the HM set operation (time from the timing t311 to the timing t312) may be longer than, for example, 100 nsec.

### Supply Voltage Margin in Set Operation

Next, with reference to FIG. 9, allowable ranges of the voltage V_{L}, the voltage V_{M}, and the voltage V_{H} supplied to the memory cell MC in each set operation of the resistance changing element VR will be described. The horizontal axis represents the value (level) of the cell voltage Vcell. The vertical axis represents a resistance value Rcell of the resistance changing element VR.

As shown in FIG. 9, as the voltage V_{L}, a voltage in a range of a voltage V_{T0} to a voltage V_{T1} may be used. Regardless of which voltage value in this range is used as V_{L}, the resistance changing element VR_LRS exhibiting the resistance value R_{L} in the low resistance state can be set.

As shown in FIG. 9, as the voltage V_{M}, a voltage in a range of the voltage V_{T1} to a voltage V_{T2} may be used. Regardless of which voltage value in this range is used as the V_{M}, the resistance changing element VR_MRS exhibiting the resistance value R_{M} in the medium resistance state can be set.

As shown in FIG. 9, as the voltage V_{H}, a voltage in a range of the voltage V_{T2} to a voltage V_{T3} may be used. Regardless of which voltage value in this range is used as V_{H}, the resistance changing element VR_HRS exhibiting the resistance value R_{H} in the high resistance state can be set.

The voltage range from the voltage V_{T0} to the voltage V_{T1}, the voltage range from the voltage V_{T1} to the voltage V_{T2}, and the voltage range from the voltage V_{T2} to the voltage V_{T3} may be, for example, a voltage range of about 2V, or may be a voltage range less than 2V or a voltage range greater than 2V.

### Electrical Characteristics of Memory Cell MC

Next, the electrical characteristics of the memory cell MC will be described with reference to FIG. 10. FIG. 10 is a schematic graph showing current-voltage characteristics of the memory cell MC according to the present embodiment. The horizontal axis represents the cell voltage Vcell. The vertical axis represents a current flowing through the memory cell MC (hereinafter, referred to as “cell current Icell”) on the logarithmic axis.

In a range where a value of the cell current Icell is smaller than a value of a predetermined current value I₁, the cell voltage Vcell increases monotonically as the cell current Icell increases. When the cell current Icell reaches the current value I₁, the cell voltage Vcell with the resistance changing element VR_LRS reaches a voltage V₁. Further, the cell voltage Vcell with the resistance changing element VR_MRS reaches a voltage V₂. The voltage V₂ is larger than the voltage V₁. Further, the cell voltage Vcell with the resistance changing element VR_HRS reaches a voltage V₃. The voltage V₃ is larger than the voltage V₂.

In a range where the value of the cell current Icell is larger than the value of the current value I₁ but smaller than a current value I₂, the cell voltage Vcell decreases monotonically as the cell current Icell increases. In this range, the cell voltage Vcell with the resistance changing element VR_HRS is larger than the cell voltage Vcell with the resistance changing element VR_MRS, and the cell voltage Vcell with the resistance changing element VR_MRS is larger than the cell voltage Vcell with the resistance changing element VR_LRS.

In a range where the cell current Icell is larger than the current value I₂ but smaller than a current value I₃, the cell voltage Vcell temporarily decreases as the cell current Icell increases, and then increases. In this range, the cell voltage Vcell with the resistance changing elements VR_HRS and VR_MRS according to the increase in the cell current Icell decreases sharply and becomes about the same as the cell voltage Vcell with the resistance changing element VR_LRS.

In a range where the cell current Icell is larger than the current value I₃, the cell voltage Vcell temporarily decreases as the cell current Icell increases, and then increases.

When the cell current Icell is rapidly reduced to a magnitude smaller than the current value I₁ from this state, an amorphous region Ra in the high resistance state is formed in the phase change layer 106. Further, when the cell current Icell is reduced to a predetermined magnitude and this state is maintained for a certain period of time and then the cell current Icell is reduced, a crystal region Rc in the low resistance state is formed in the phase change layer 106.

### Comparative Example

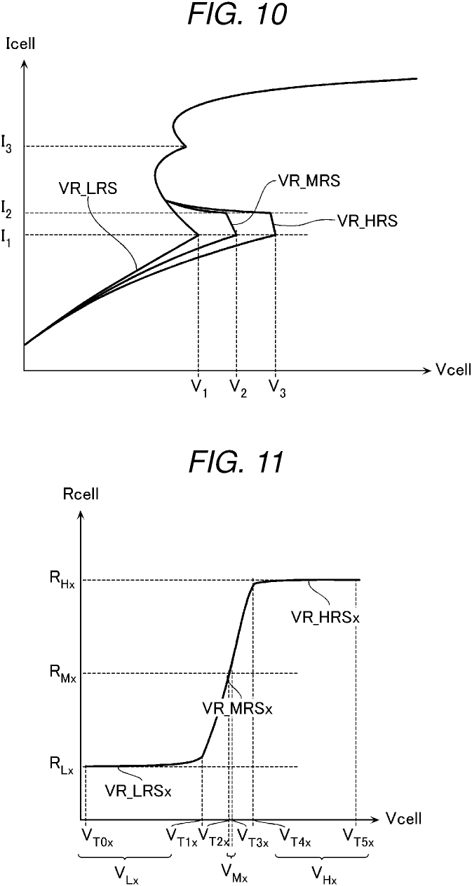

Next, with reference to FIG. 11, an allowable range of a voltage supplied to the memory cell MC in each set operation of the resistance changing element VRx according to the comparative example will be described. The horizontal axis represents the cell voltage Vcell. The vertical axis represents the resistance value Rcell of the resistance changing element VRx.

The resistance changing element VRx according to the comparative example does not provide a temperature gradient or a composition gradient during heating and heat dissipation, and an intermediate state such as the second phase 106_M cannot be stably formed.

In FIG. 11, as the three resistance states of the resistance changing element VRx according to the comparative example, a resistance changing element VR_LRSx which is in the low resistance state, a resistance changing element VR_MRSx which is in the medium resistance state, and a resistance changing element VR_HRSx which is in the high resistance state are shown. Further, FIG. 11 shows a resistance value R_{Lx}, a resistance value R_{Mx}, and a resistance value R_{Hx}.

A voltage V_{Lx} is supplied to set the resistance changing element VRx according to the comparative example to the resistance changing element VR_LRSx. As shown in FIG. 11, as the voltage V_{Lx}, for example, a voltage in a range of a voltage V_{T}₀ₓ to a voltage V_{T}₁ₓ is used.

A voltage V_{Hx} is supplied to set the resistance changing element VRx according to the comparative example to the resistance changing element VR_HRSx. As shown in FIG. 11, as the voltage V_{Hx}, for example, a voltage in a range of a voltage V_{T}_{4X} to a voltage V_{T}₅ₓ is used.

A voltage V_{Mx} is supplied to set the resistance changing element VRx according to the comparative example to the resistance changing element VR_MRSx which is in the medium resistance state. As the voltage V_{Mx}, as shown in FIG. 11, a voltage in a range from a voltage V_{T}₂ₓ larger than the voltage V_{T}₁ₓ to a voltage V_{T}₃ₓ smaller than the voltage V_{T}_{4X} is used. Here, since the second phase 106_M is not stably formed in the resistance changing element VRx according to the comparative example, a voltage range (from the voltage V_{T}₂ₓ to the voltage V_{T}₃ₓ) for setting the resistance value R_{Mx} is relatively narrow. Therefore, if value of the voltage V_{Mx} supplied during the set operation varies only slightly, the resistance value R_{Mx} may vary greatly.

### Effect

In order to stably perform the set operation on the three resistance states, it is generally preferable that an allowable voltage range of the voltage V_{M} supplied to the memory cell MC be wider, especially in the set operation to the resistance changing element VR_MRS which is in the medium resistance state.

Therefore, in an embodiment, by generating a temperature gradient and a composition gradient in the phase change layer 106, it is possible to stably divide the regions into the amorphous region Ra in the region R11 and the crystal region Rc in the region R12, as described with reference to, for example, FIG. 5. Thereby, the medium resistance state can be formed in a wider voltage range (for example, from the voltage V_{T1} to the voltage V_{T2} in FIG. 9).

Further, in an embodiment, since three separate resistance states can be stably formed, ternary information (1.5 bits) can be stably stored in each resistance changing element VR. Therefore, it is possible to increase a recording density and provide a large-capacity storage element as compared with an element that stores only binary information (1 bit) in a resistance changing element VR.

### Structural Example of Memory Cell MC Suitable for Forming Temperature Gradient

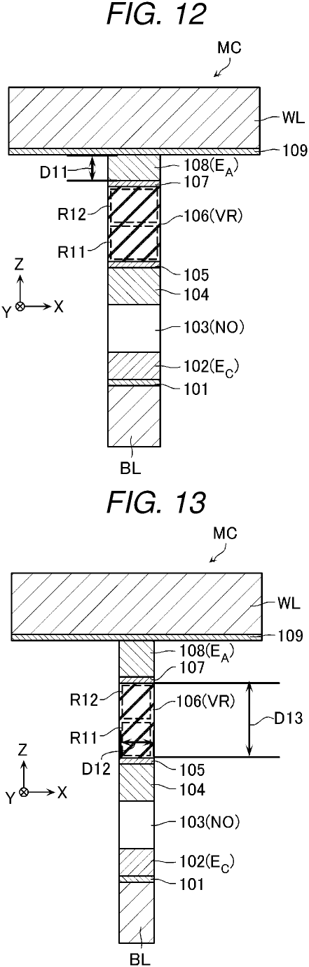

Next, an example of a memory cell MC suitable for forming a temperature gradient in an element will be described with reference to FIGS. 12 and 13. FIGS. 12 and 13 are schematic cross-sectional views of the memory cell MC according to an embodiment.

### Structure With High Thermal Conductivity on Anode E_{A} Side

As shown in FIG. 12, the memory cell MC may be provided with the conductive layer 108 on the anode E_{A} side having a relatively thin width D11. Since a film thickness of the conductive layer 108 is relatively thin, heat dissipation is further promoted to the word line WL side, which is a metal wiring, via the conductive layer 108. The width D11 may be, for example, 10 nm or less.

Further, heat dissipation may be promoted to the word line WL side due to the relatively high thermal conductivity of the material configuring the conductive layer 108. The thermal conductivity of the material configuring the conductive layer 108 may be, for example, 2 × 10⁻² W/K/cm or more.

The thermal conductivity of the materials contained in the conductive layer 108 can be estimated from the literature values and the like based on the measured values of the composition, crystal structure, and the like of the configuring materials.

### Structure With High Aspect Ratio of Phase Change Layer 106

As shown in FIG. 13, the memory cell MC may be provided in a structure having a relatively high aspect ratio for the phase change layer 106. The aspect ratio means a ratio of a width D13 in the Z direction to a width D12 in the X direction or the width D13 in the Z direction to a width in the Y direction (not shown). Since heat is dissipated from the anode E_{A} side, a temperature difference between the region R11 and the region R12 is likely to be formed due to the relatively high aspect ratio. As the aspect ratio of the phase change layer 106, for example, the width D13 / width D12 may be 1.5 or more.

### Second Embodiment

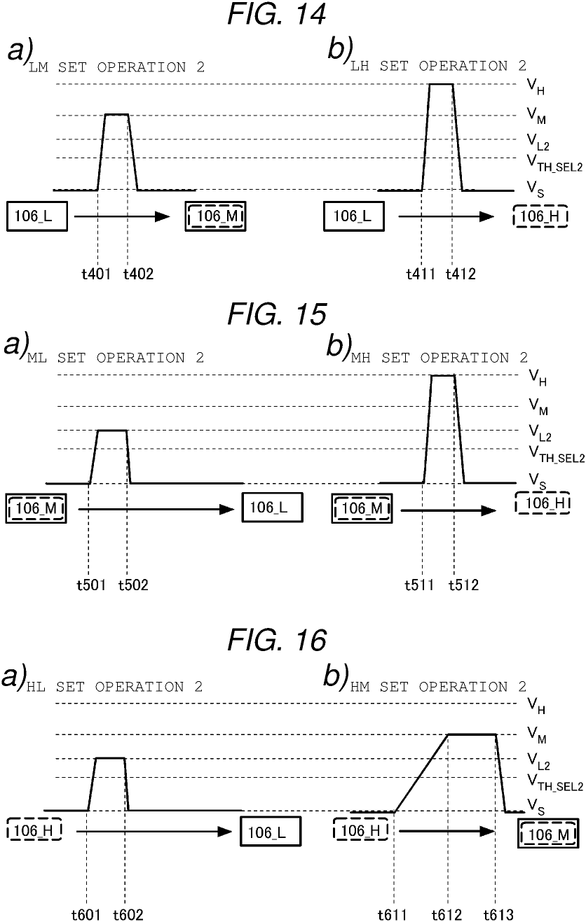

Next, a semiconductor storage device according to a second embodiment will be described with reference to FIG. 14 to FIG. 16. FIG. 14 to FIG. 16 are schematic waveform diagrams illustrating a set operation of the semiconductor storage device according to the second embodiment and show operations corresponding to FIG. 6 to FIG. 8. In the following description, additional description of aspects and operations that are the same as in the first embodiment may be omitted.

The semiconductor storage device according to the second embodiment is basically configured in the same manner as the semiconductor storage device according to the first embodiment and the same operations can be performed. However, the semiconductor storage device according to the second embodiment performs an LM set operation 2 instead of the LM set operation, an LH set operation 2 instead of the LH set operation, an ML set operation 2 instead of the ML set operation, an MH set operation 2 instead of the MH set operation, an HL set operation 2 instead of the HL set operation, and an HM set operation 2 instead of the HM set operation. Furthermore, in the semiconductor storage device according to the second embodiment, the selector layer 103 has a threshold voltage V_{TH_SEL2} lower than the threshold voltage V_{TH_SEL}.

### LM Set Operation 2

The LM set operation 2 is almost the same as the LM set operation. In the LM set operation 2, as shown in FIG. 14, part a, the voltage V_{M} begins to be supplied to the memory cell MC at a timing t401, and the voltage V_{S} is supplied at a timing t402. By the LM set operation 2, the phase change layer 106 changes to the second phase 106_M in the medium resistance state.

### LH Set Operation 2

The LH set operation 2 is almost the same as the LH set operation. In the LH set operation 2, as shown in FIG. 14, part b, the voltage V_{H} begins to be supplied to the memory cell MC at a timing t411, and the voltage V_{S} is supplied at a timing t412. By the LM set operation 2, the phase change layer 106 changes to the third phase 106_H in the high resistance state.

### ML Set Operation 2

In the ML set operation 2, as shown in FIG. 15, part a, a voltage V_{L2} begins to be supplied to the memory cell MC at a timing t501, and the voltage V_{L2} is supplied from the timing t501 to a timing t502, and then, the voltage V_{S} is supplied. The voltage V_{L2} is larger than the threshold voltage V_{TH_SEL2} of the selector layer 103 but smaller than the voltage V_{M}. By supplying the voltage V_{L2} from the timing t501 to the timing t502, both the region R11 and the region R12 are heated to a temperature that is lower than the melting temperature but higher than the crystallization temperature to form the crystal region Rc. By the ML set operation 2, the phase change layer 106 changes to the first phase 106_L in the low resistance state.

### MH Set Operation 2

The MH set operation 2 is almost the same as the MH set operation. In the MH set operation 2, as shown in FIG. 15, part B, the voltage V_{H} begins to be supplied to the memory cell MC at a timing t511, and the voltage V_{S} is supplied at a timing t512. By the MH set operation 2, the phase change layer 106 changes to the third phase 106_H in the high resistance state.

### HL Set Operation 2

In the HL set operation 2, as shown in FIG. 16, part a, the voltage V_{L2} begins to be supplied to the memory cell MC at a timing t601, the voltage V_{L2} is supplied from the timing t601 to a timing t602, and then the voltage V_{S} begins to be supplied at the timing t602. By the HL set operation 2, the phase change layer 106 changes to the first phase 106_L in the low resistance state.

### HM Set Operation 2

The HM set operation 2 is almost the same operation as the HM set operation. In the HM set operation 2, as shown in FIG. 16, part b, a voltage begins to be supplied to the memory cell MC from a timing t611 until a timing t612. The supplied voltage increases during this time period from the voltage V_{S} to the voltage V_{M}. Next, the voltage V_{M} is supplied to the memory cell MC from the timing t612 to a timing t613, and then the voltage V_{S} begins to be supplied at the timing t613. By the HM set operation 2, the phase change layer 106 changes to the second phase 106_M in the medium resistance state.

### Other Embodiments

A semiconductor storage device according to a first embodiment and a second embodiment are described above. However, these semiconductor storage devices are merely examples and the specific configuration and the like can be appropriately adjusted or varied.

For example, in the examples of FIGS. 1 and 2, two memory mats MM are located in the Z direction. The lower memory mat MM includes a bit line BL located below and a word line WL located above, and the upper memory mat MM includes a word line WL located below and a bit line BL located above. Furthermore, the word line WL is provided in common for the memory mat MM located below and the memory mat MM located above. However, in other examples, the bit line BL shown in FIG. 2 may be replaced with the word line WL, and the word line WL shown in FIG. 2 may be replaced with the bit line BL.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a first electrode and a second electrode separated in a first direction; and
a phase change layer between the first electrode and the second electrode and comprising at least one of germanium (Ge), antimony (Sb), and tellurium (Te), wherein
the phase change layer is configured to be able to transition to a first state in which a volume ratio of an amorphous phase to a crystalline phase is a first ratio, a second state in which the volume ratio is a second ratio larger than the first ratio, and a third state in which the volume ratio is a third ratio larger than the second ratio.

2. The semiconductor storage device according to claim 1, wherein
the phase change layer includes a first region and a second region closer to the first electrode than the first region, and
a volume ratio of the amorphous phase to the crystalline phase in the second region is smaller than a volume ratio of the amorphous phase to the crystalline phase in the first region when the phase change layer is in the second state.

3. The semiconductor storage device according to claim 1, wherein a width of the first electrode in the first direction is smaller than 10 nm.

4. The semiconductor storage device according claim 1, wherein the phase change layer contains 10% to 90% of the crystalline phase with respect to the total volume of the phase change layer in the second state.

5. The semiconductor storage device according to claim 1, wherein, when a width of the phase change layer in the first direction is a first width and a width of the phase change layer in a second direction intersecting the first direction is a second width, the first width is at least 1.5 times the second width.

6. The semiconductor storage device according to claim 1, wherein
the phase change layer transitions from the first state to the second state by application of a first voltage, and
the phase change layer transitions from the first state to the third state by application of a second voltage larger than the first voltage.

7. The semiconductor storage device according to claim 6, wherein
the phase change layer transitions from the second state to the first state by application of a third voltage at a first time, and then application of a fourth voltage smaller than the third voltage at a second time, and
the phase change layer transitions from the second state to the third state by application of a fifth voltage larger than the third voltage.

8. The semiconductor storage device according to claim 7, wherein
the phase change layer transitions from the third state to the first state by application of a sixth voltage at a third time, and then application of a seventh voltage smaller than the sixth voltage at a fourth time, and
the phase change layer transitions from the third state to the second state by application of a voltage that monotonically increases from an eighth voltage to a ninth voltage larger than the eighth voltage from the fifth time to a sixth time, and then application of the ninth voltage from the sixth time to a seventh time.

9. The semiconductor storage device according to claim 1, wherein a positive voltage is applied to the first electrode in a read operation and a write operation.

10. The semiconductor storage device according to claim 1, further comprising:
a first wiring extending in a third direction intersecting the first direction; and
a second wiring extending in a fourth direction intersecting the first direction and the third direction, wherein
the first electrode and the second electrode are provided between the first wiring and the second wiring.

11. A memory device, comprising:
a word line;
a bit line separated from the word line in a first direction;
a memory cell between the word line and the bit line in the first direction, the memory cell including:
an anode electrode contacting the word line;
a variable resistance element contacting the anode electrode, the anode electrode being between the variable resistance element and the word line in the first direction;
a conductor layer contacting the variable resistance element, the variable resistance element being between the anode electrode and the conductor layer in the first direction;
a switch element contacting the conductor layer, the conductor layer being between the switch element and the variable resistance element in the first direction; and
a cathode electrode between the switch element and the bit line, wherein
the variable resistance element comprises a first region and a second region, the first region being closer to the conductor layer than is the second region,
the variable resistance element has a high resistance state in which a volume ratio of the variable resistance element is greater than 90% amorphous phase, a low resistance state in which the volume ratio is greater than 90% crystalline phase, and an intermediate resistance state in which the volume ratio is between 10% and 90% crystalline phase,
a volume ratio of the first region is greater than 90% amorphous in the intermediate resistance state, and
a volume ratio of the second region is less than 90% amorphous in the intermediate state.

12. The memory device according to claim 11, wherein the first region has a different composition from the second region.

13. The memory device according to claim 11, wherein
the first and second regions are a Ge—Sb—Te based chalcogenide compound, and
the amount of tellurium in the first region is less than the amount of tellurium in the second region.

14. The memory device according to claim 11, wherein
the variable resistance element includes a phase change layer, and
a ratio of the length of the phase change layer in the first direction to a width of the phase change layer in a second direction perpendicular the first direction is at least 1.5:1.

15. The memory device according to claim 14, wherein the phase change layer is a Ge—Sb—Te based chalcogenide compound.

16. The memory device according to claim 14, wherein a thickness of the first electrode in the first direction is less than 10 nm.

17. The memory device according to claim 11, wherein a thickness of the first electrode in the first direction is less than 10 nm.

18. A semiconductor storage device, comprising:
a first electrode and a second electrode separated in a first direction; and
a phase change layer between the first electrode and the second electrode, wherein
the phase change layer is configured to be able to transition to a first state in which a volume ratio of an amorphous phase to a crystalline phase is a first ratio, a second state in which the volume ratio is a second ratio larger than the first ratio, and a third state in which the volume ratio is a third ratio larger than the second ratio.

19. The semiconductor storage device according to claim 18, wherein
the phase change layer includes a first region and a second region closer to the first electrode than the first region, and
a volume ratio of the amorphous phase to the crystalline phase in the second region is smaller than a volume ratio of the amorphous phase to the crystalline phase in the first region when the phase change layer is in the second state.

20. The semiconductor storage device according to claim 19, wherein the phase change layer is a Ge—Sb—Te based chalcogenide compound with a first region having a higher tellurium concentration than a second region.
